(19) United States
(12) Patent Application Publication
(10) Pub. No.: US 2008/0164582 A1
(43) Pub. Date: Jul. 10, 2008

(54) Semiconductor devices and methods of manufacture thereof

(76) Inventor: Shrinivas Govindarajan, Austin, TX (US)

Correspondence Address: SLATER & MATSIL LLP, 17950 PRESTON ROAD, SUITE 1000, DALLAS, TX, 75252, US

(21) Appl. No.: 11/650,055

(22) Filed: Jan. 5, 2007

(51) Int. Cl. H01L 23/58; H01L 21/44

(52) U.S. Cl. 257/635; 438/652; 257/E21.476; 257/E23.001

(57) ABSTRACT

Semiconductor devices and methods of manufacture thereof are disclosed. In one embodiment, a method of fabricating a semiconductor device includes providing a workpiece, and forming a dielectric layer over the workpiece. The dielectric layer comprises a crystalline phase. The method includes forming an electrode material over the dielectric layer.

### TECHNICAL FIELD

The present invention relates generally to the fabrication of semiconductors, and more particularly to high dielectric constant insulating materials and methods of formation thereof.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (IC's). There may be a plurality of transistors, memory devices, switches, conductive lines, diodes, capacitors, logic circuits, and other electronic components formed on a single die or chip.

Insulating materials comprise dielectric materials that are used in many types of semiconductor devices. Silicon dioxide (SiO₂) is a common dielectric material used in semiconductor device manufacturing, for example, which has a dielectric constant or k value of about 3.9. Some semiconductor applications require the use of a high k dielectric material having a higher k value than the k value of silicon dioxide, for example. Some transistors require a high k dielectric material as a gate dielectric material, and some capacitors require a high k dielectric material as an insulating material between two conductive plates, as examples, to reduce leakage current and reduce capacitance.

A dynamic random access memory (DRAM) is a memory device that can be used to store information. A DRAM cell in a memory array typically includes two elements: a storage capacitor and an access transistor. Data can be stored into and read out of the storage capacitor by passing a charge through the access transistor and into the capacitor. The capacitance, or the amount of charge held by the capacitor per applied voltage, is measured in farads and depends upon the area of the plates, the distance between them, and the dielectric value of the insulator, as examples.

High k dielectric materials are typically used as an insulating material in the storage capacitor of DRAM cells. Examples of some high dielectric constant materials that have been proposed as capacitor dielectric materials are hafnium oxide and hafnium silicate. However, these materials are limited to a maximum dielectric constant of around 30, for example.

What are needed in the art are improved high dielectric constant (k) dielectric materials and methods of formation thereof in semiconductor devices.

### SUMMARY OF THE INVENTION

These and other problems are generally solved or circumvented, and technical advantages are generally achieved, by preferred embodiments of the present invention, which provide improved methods of forming high k dielectric materials and structures thereof.

In accordance with a preferred embodiment of the present invention, a method of fabricating a semiconductor device includes providing a workpiece, and forming a dielectric layer over the workpiece. The dielectric layer comprises a crystalline phase. The method includes forming an electrode material over the dielectric layer.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a flow chart illustrating methods of manufacturing semiconductor devices in accordance with preferred embodiments of the present invention;

FIGS. 2 through 11 show cross-sectional views of a semiconductor device in accordance with preferred embodiments of the present invention at various stages of manufacturing;

FIGS. 12 and 13 show cross-sectional views of a semiconductor device at various stages of manufacturing, wherein the novel methods of embodiments of the present invention are implemented in a metal-insulator-metal (MIM) capacitor structure;

FIG. 14 shows a cross-sectional view of a semiconductor device, wherein the novel methods of embodiments of the present invention are implemented in a transistor structure; and

FIGS. 15 and 16 show cross-sectional views of a semiconductor device at various stages of manufacturing, wherein the novel methods of embodiments of the present invention are implemented in a DRAM structure.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The development of high k dielectric materials has conventionally focused on the development of amorphous high k material layers, the conventional belief being that amorphous materials avoid grain boundaries which are potential pathways for high leakage current.

Some embodiments of the present invention provide novel methods of forming and structures for crystalline high k material layers. I have discovered processing pathways with the novel crystalline high k materials described herein that provide extremely low leakage currents. Other embodiments of the present invention provide novel methods of forming and structures for multiple layer or gettering electrodes.

The present invention will be described with respect to preferred embodiments in specific contexts, namely the formation of high k dielectric materials and electrodes in semiconductor devices such as capacitors and transistors. The invention may also be applied, however, to the formation of dielectric materials in other applications where high k dielectric materials are required, for example, and in other applications where electrodes are used.

Embodiments of the present invention achieve technical advantages by providing novel processing solutions for the formation of high k dielectric materials and electrodes. The novel dielectric materials to be described herein have high k values, low leakage currents, good uniformity, and high temperature thermal stability. The novel electrode materials and methods of forming thereof have increased diffusion barrier properties, have decreased leakage, and minimally impact the effective oxide thickness (EOT) of the dielectric material layers disposed beneath the electrode materials.

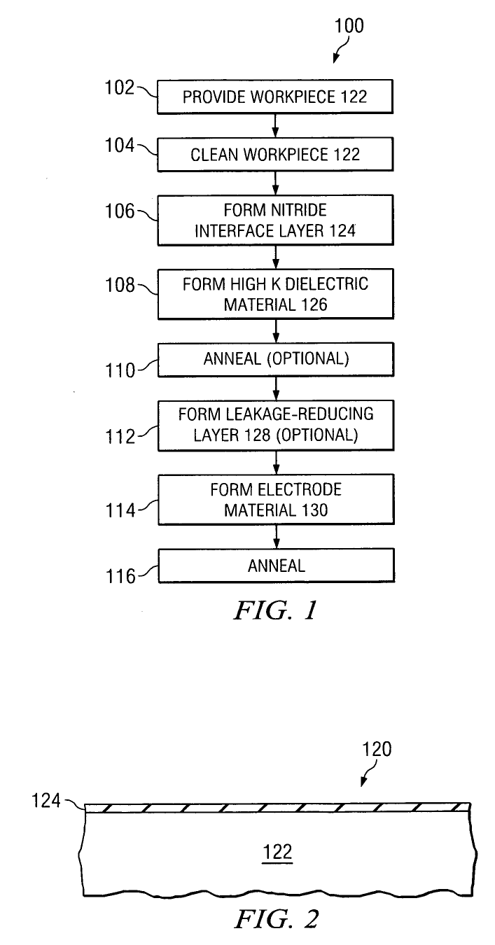

FIG. 1 is a flow chart 100 illustrating methods of manufacturing a semiconductor device 120 (see FIG. 2) in accordance with preferred embodiments of the present invention. The flow chart 100 will first be described generally, and later the steps of the flow chart 100 will be described in detail with respect to several preferred embodiments of the present invention.

First, a workpiece 122 is provided (step 102), and the workpiece 122 is cleaned (step 104). A nitride interface layer 124 is formed over the workpiece (step 106). A high k dielectric material 126 is formed over the nitride interface layer 124 (step 108). An optional anneal process is performed (step 110), and a leakage-reducing layer 128 may optionally be formed over the high k dielectric material 126 (step 112). An electrode material 130 is formed over the high k dielectric material 126, or over the leakage-reducing layer 128, if present (step 114). An anneal process is then performed (step 116).

In some embodiments, the electrode material 130 comprises a double layer top metal electrode. In other embodiments, the electrode material 130 includes a gettering layer disposed therein or at a top surface thereof. In other embodiments, the high k dielectric material 126 comprises a crystalline high k phase of a dielectric material 126, such as in-situ nitrided hafnium silicon oxynitride (HfSiON), hafnium silicate (HfSiO), or other insulating materials. One or more of these features may be used to fabricate semiconductor devices in accordance with embodiments of the present invention, for example. These novel features and combinations thereof advantageously achieve low leakage current devices with a reduced EOT.

Several preferred embodiments of the present invention will next be described. In accordance with a first embodiment, the electrode material 130 comprises a double layer top metal electrode. A cross-sectional view of a semiconductor device 120 at various stages of manufacturing in this embodiment is shown in FIGS. 2 through 7, 9, and 11.

The semiconductor device 120 is preferably fabricated by providing a workpiece 122 (step 102 of FIG. 1), as shown in FIG. 2. The workpiece 122 may include a semiconductor substrate comprising silicon or other semiconductor materials covered by an insulating layer, for example. The workpiece 122 may also include other active components or circuits, not shown. The workpiece 122 may comprise silicon oxide over single-crystal silicon, for example. The workpiece 122 may include other conductive layers or other semiconductor elements, e.g., transistors, diodes, etc. Compound semiconductors, GaAs, InP, Si/Ge, or SiC, as examples, may be used in place of silicon. The workpiece 122 may comprise a silicon-on-insulator (SOI) substrate, for example.

The workpiece 122 is cleaned (step 104 of FIG. 1). For example, the workpiece 122 may be cleaned to remove debris, native oxide, and/or contaminants. In a preferred embodiment, the workpiece 122 is cleaned using a hydrogen fluoride (HF) “last” or final cleaning step, for example. Alternatively, other chemicals and processes may be used to clean the workpiece 122, for example.

A nitride interface layer 124 is formed over the workpiece 122 (step 106 of FIG. 1), as shown in FIG. 2. The nitride interface layer 124 preferably comprises silicon oxynitride (SiOₓN_{y}), although alternatively, the interface layer 124 may comprise other insulating materials including nitrogen, for example. In a preferred embodiment, the nitride interface layer 124 is preferably formed by growing an oxide using a well-controlled growth process, followed by nitriding the well-controlled oxide by exposing the oxide to a rapid thermal anneal (RTA) process in an ambient of NH₃ at a pressure of around 20 to 40 Torr for about 45 to 75 seconds, at a temperature of about 500° C. to 900° C., as examples, although alternatively, other processing parameters may also be used. This anneal process is also referred to herein as a pre-anneal process, for example. The nitride interface layer 124 preferably comprises a thickness of about 1 nm or less, for example, although alternatively, the nitride interface layer 124 may comprise other dimensions. The nitride interface layer 124 preferably comprises an oxynitride material in some embodiments, for example.

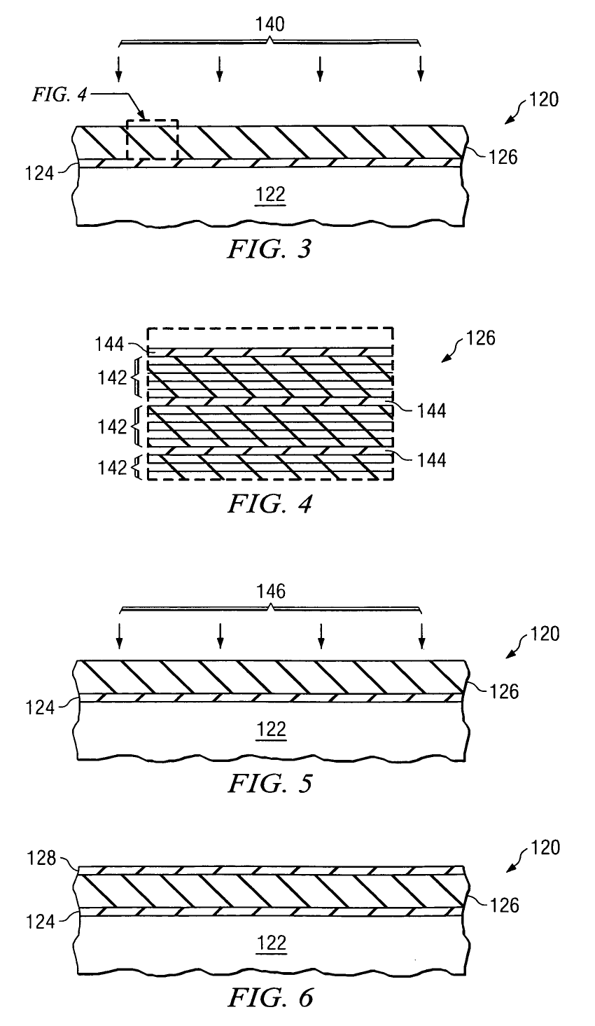

Next, a dielectric layer 126 is formed over the nitride interface layer 124, as shown in FIG. 3 (step 108 of FIG. 1). The dielectric layer 126 preferably comprises a dielectric material having a high dielectric constant (k), e.g., having a k value of greater than about 3.9, for example. The dielectric layer 126 is also referred to herein as a high k dielectric material 126, for example.

The deposition process 140 for the dielectric layer 126 preferably comprises in-situ nitridation of a dielectric material and/or forming a dielectric material having a crystalline phase in some embodiments, for example. The dielectric layer 126 preferably comprises at least one layer of HfSiON in some embodiments, as an example, although other materials may also be used, such as ZrSiON, LaSiON, or other materials. The dielectric layer 126 preferably comprises a thickness of about 20 nm or less, for example, although alternatively, the dielectric layer 126 may comprise other dimensions. The target thickness of the dielectric layer 126 as deposited may comprise about 8 to 18 nm for DRAM applications, and may comprise about 2 to 5 nm for transistor applications, as examples.

In some embodiments, forming the dielectric layer 126 preferably comprises forming the dielectric layer 126 using atomic layer deposition (ALD). The deposition process 140 may comprise a plurality of alternating ALD cycles, e.g., for the formation of a dielectric material such as HfSiON, comprising the steps of: flowing Hf and Si containing precursors such as a mixture of tetrakis ethylmethylamido hafnium (TemaHf) and tetrakis ethylmethylamido silicon (TemaSi) over the nitride interface layer 124 in a chamber; purging the chamber of the mixture of TemaHf and TemaSi; introducing a reactant such as NH₃ into the chamber; purging the chamber of the NH₃; annealing the workpiece after about five ALD cycles (or alternatively, after other predetermined numbers of ALD cycles) in an ambient of 03, e.g., at a temperature of about 250 to 400 degrees C.; and repeating the steps of flowing the mixture of TemaHf and TemaSi, purging the chamber of the mixture of TemaHf and TemaSi, introducing NH₃ into the chamber, purging the chamber of the NH₃, and annealing the workpiece, until a desired thickness of the dielectric layer 126 is obtained, e.g., about 20 nm or less, although the dielectric layer 126 may also comprise other dimensions. The precursors TemaHf and TemaSi and the reactant NH₃ may be introduced into the chamber until the surface of the nitride interface layer 124 is fully saturated, and then the chamber may be purged, for example. The purging steps may comprise flowing an inert gas such as argon (Ar) into the chamber, which removes any excess reactant or precursors from the chamber, for example. The deposition process 140 may comprise a wafer or workpiece 122 temperature of about 295 to 365 degrees C. at a chamber pressure of about 1 Torr, for example, although alternatively, other processing parameters may also be used. Alternatively, other precursors, reactants, and conditions may be used to form other types of high k dielectric materials 126, for example.

FIG. 4 shows a more detailed view of the dielectric layer 126 in this embodiment. Exposure to the precursors and the NH₃ forms a plurality of thin layers of HfSiN 142, and exposing the HfSiN 142 layers to O₃ forms a layer of HfSiON 144 over the HfSiN 142 layers, as shown. Each ALD deposited layer 142 and 144 may comprise a thickness of an Angstrom or less, e.g., about 0.7 Angstroms of material may be formed for each ALD cycle. Subsequent annealing processes cause movement of the oxygen (O) from the HfSiON 144 layers to the HfSiN 142 layers to form a multi-layer stack of a plurality of HfSiON layers 142/144, for example.

Alternatively, the dielectric layer 126 may comprise a single material layer or two or more layers of a material as deposited, for example. The dielectric layer 126 preferably comprises a predominantly tetragonal HfO₂ structure in some embodiments, for example. Forming the dielectric layer 126 may comprise in-situ nitridation of HfSiON or HfSiO, for example, over the nitride interface layer 124. Alternatively, forming the dielectric layer 126 may comprise in-situ nitridation of other materials, such as ZrSiON, ZrSiO, LaSiON, LaSiO, or other materials, as examples, in accordance with embodiments of the present invention. In other embodiments, the dielectric layer 126 may not be crystalline and may not be formed by in-situ nitridation, for example.

The workpiece 122, e.g., the dielectric layer 126 disposed over the workpiece 122, is then annealed using an optional anneal process 146, as shown in FIG. 5 (step 110 of FIG. 1). The anneal process 146 preferably comprises a post deposition anneal process in a nitrogen ambient. For example, the workpiece 122 may be annealed in an ambient of NH₃ at a pressure of about 20 to 40 Torr for about 45 to 75 seconds at a temperature of about 500° C. to 900° C., although alternatively, other processing parameters may also be used. The optional post deposition anneal process 146 densifies the dielectric layer 126 and results in the further inclusion of additional nitrogen molecules into the dielectric layer 126, advantageously.

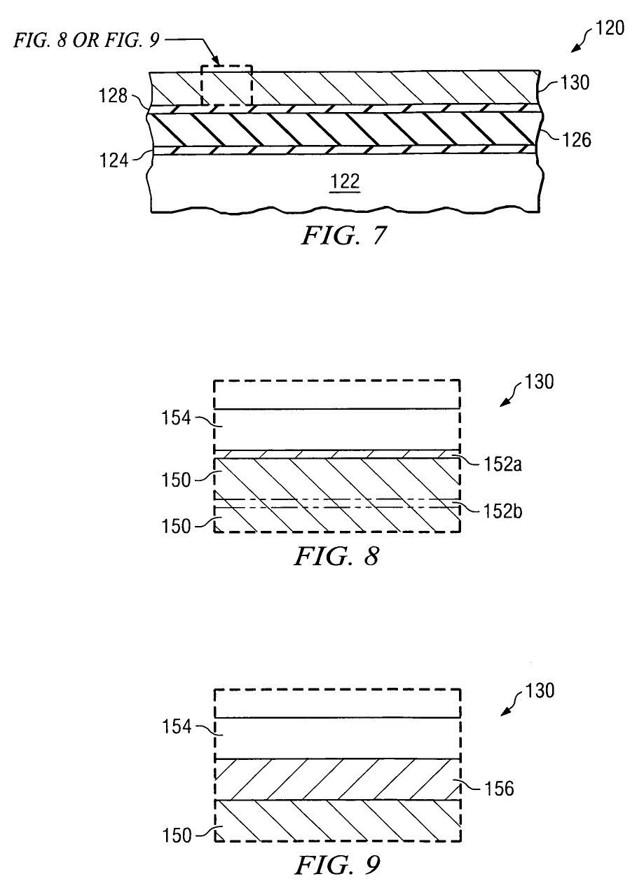

An optional leakage-reducing layer 128 may be formed over the dielectric layer 126 (step 112 of FIG. 1), as shown in FIG. 6. The leakage-reducing layer 128 preferably comprises a material adapted to reduce leakage current of the semiconductor device 120, for example. However, alternatively, the leakage-reducing layer 128 may not be included: an electrode material 130 (see FIG. 7) may be formed directly over the dielectric layer 126. The dielectric layer 126 may include a top layer that comprises the leakage-reducing layer 128, for example. Forming the dielectric layer 126/128 in this embodiment may comprise forming a first insulating material 126 and forming a second insulating material 128 over the first insulating material 126, wherein the second insulating material 128 comprises the leakage-reducing layer. The leakage-reducing layer 128 may comprise about 30 Angstroms or less of Al₂O₃, for example, although the leakage-reducing layer 128 may comprise other materials and dimensions. More preferably, the leakage-reducing layer 128 comprises a thickness of about 4 to 20 Angstroms, for example. The leakage-reducing layer 128 preferably completely covers the surface of the dielectric layer 126, for example. The leakage-reducing layer 128 may also comprise HfOₓ, HfSiOₓ, or other materials, wherein x indicates the stoichiometry of the material.

An electrode material 130 is then formed over the dielectric layer 126 (step 114 in FIG. 1), or over the leakage-reducing layer 128 if present in the structure, as shown in FIG. 7. FIG. 9 shows a more detailed view of the electrode material 130 in this embodiment. The electrode material 130 is preferably formed by forming a first material layer 150 over the dielectric layer 126 (or leakage-reducing layer 128), and forming at least one second material layer 156 over the first material layer 150. The at least one second material layer 156 is different than the first material layer 150; e.g., the second material layer 156 preferably comprises a different material than the material of the first material layer 150.

The first and second material layers 150 and 156 of the electrode material 130 preferably comprise conductive materials. The first material layer 150 is also referred to herein as a first conductive material, and the second material layer 156 is also referred to herein as a second conductive material, for example.

Preferably, in some embodiments, the electrode material 130 is formed by placing the workpiece 122 in a chamber (not shown), applying a vacuum to the chamber, and forming the first conductive material 150 and the at least one second conductive material 156 while maintaining the vacuum in the chamber, without removing the workpiece 122 from the chamber, for example.

The first conductive material 150 preferably comprises a thickness of about 10 nm or less, and more preferably comprises a thickness of about 70 to 150 Angstroms of a material such as TaCN deposited by ALD. The second conductive material 156 preferably comprises a thickness of about 10 nm or less, and more preferably comprises a thickness of about 70 to 150 Angstroms of a material such as TiN deposited by ALD. Alternatively, the first and second conductive materials 150 and 156 may comprise other materials and dimensions and may be formed using other deposition techniques, for example. The first conductive material 150 preferably comprises a high work function material, e.g., comprising a higher work function than the second conductive material 156, for example. The first conductive material 150 may alternatively comprise TiSiN, TiHfN, or MoAlN, as examples, in this embodiment, although other materials may also be used. The second conductive material 156 preferably comprises an oxygen diffusion barrier metal, for example. The second conductive material 156 may alternatively comprise TaN, for example, although other materials may also be used. The first and second conductive materials 150 and 156 may be formed using ALD or MOCVD, or alternatively, other deposition techniques may also be used.

The electrode material 130 preferably includes an optional layer of semiconductive material 154 disposed over the second material layer 156, as shown in FIG. 9. The layer of semiconductive material 154 preferably comprises about 100 nm of polysilicon, as an example, although alternatively, the layer of semiconductive material 154 may comprise other materials and dimensions. The semiconductive material 154 may be doped with dopants to increase the conductivity of the semiconductive material 154, for example.

Next, the workpiece 122 is annealed (step 116 of FIG. 1) using an anneal process 160, as shown in FIG. 11. The anneal process 160 preferably comprises an activation anneal comprising a temperature greater than the temperature of the pre-anneal process to form the nitride interface layer 124 or the post deposition anneal process 146 shown in FIG. 5, for example. The anneal process 160 preferably comprises a temperature of greater than about 1,000 degrees C., for example. The anneal process 160 may comprise an anneal process at about 1050° C. for about 30 seconds in an N₂ ambient or other nitrogen ambient, as an example. The anneal process 160 may comprise an anneal process for greater than about 10 seconds in an ambient of N₂, wherein the N₂ concentration is greater than about 90%, an another example. The anneal process 160 may comprise a high temperature rapid thermal process in a nitrogen rich ambient for greater than about 5 seconds in other embodiments, for example. Alternatively, other processing parameters may be used for the anneal process 160.

Advantageously, in accordance with some embodiments of the present invention, by selecting an appropriate high k material for the dielectric layer 126, for example, in-situ nitrided hafnium silicon oxynitride, hafnium silicate, or other materials, and by subjecting the dielectric layer 126 to a high temperature rapid thermal anneal treatment (e.g., anneal process 160) above 1,000° C., the dielectric layer 126 crystallizes into a predominantly tetragonal structure, resulting in low EOT and low leakage current density for the semiconductor device 120. The anneal process 160 preferably comprises a temperature sufficient to crystallize the dielectric layer 126 in some embodiments, for example.

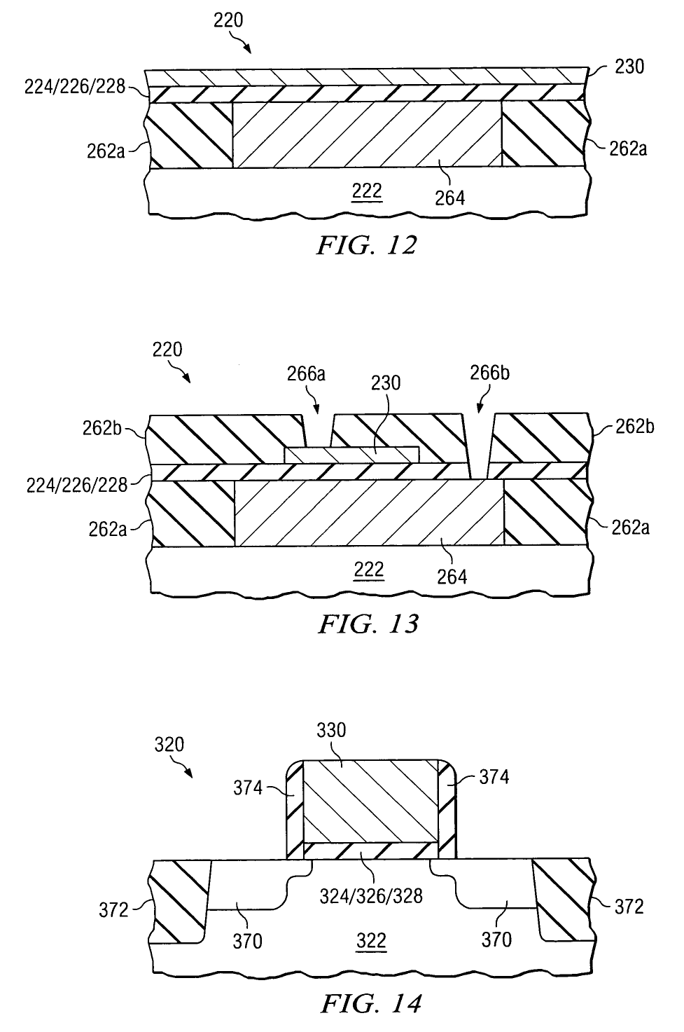

The material layers 130, 128, 126, and 124 may then be patterned using lithography to form transistors or capacitors from at least the electrode material 130 and the dielectric layer 126 or 126/128 and nitride interface layer 124 (not shown in FIG. 11; see FIGS. 12 through 16 which will be described later herein).

The embodiment shown in and described with reference to FIGS. 2 through 7, 9, and 11 provides novel processing pathways and material selections that achieve a low leakage current and a low EOT, e.g., of the insulating materials 124, 126, and 128 and electrode material 130. This embodiment is especially useful in metal-insulator-metal (MIM) capacitors, for DRAM applications, and for metal insulator semiconductor (MIS) capacitor applications, as examples.

Experimental results have shown that the use of a novel double metal electrode 130 comprising the first conductive material 150 comprising TaCN and the second conductive material 156 comprising TiN deposited without a vacuum break and combined with a dielectric layer 126 comprised of a material having a predominantly tetragonal HfO₂ structure in accordance with embodiments of the present invention advantageously results in a highly effective work function (EWF) metal electrode 130 and also results in a system having a low leakage current; e.g., less than about 1×10⁻⁷A(Amperes)/cm² and a low EOT; e.g., of less than about 2 nm. The bi-layer electrode material 130 functions as a diffusion barrier for oxygen during the activation anneal process 160 shown in FIG. 11, preventing growth of the nitride interface layer 124 during the activation anneal process 160. The optional use of the leakage-reducing layer 128 comprised of Al₂O₃ disposed directly below the metal electrode 130 was found to reduce leakage current. The bi-layer electrode material 130 comprised of these materials minimizes flatband voltage hysteresis and the rate of increase of the flatband voltage hysteresis with EOT. A further reduction in EOT may be achieved by optimization of the ammonia-based pre-anneal anneal process used to form the nitride interface layer 124 shown in FIG. 2, for example.

The high temperature anneal process 160 crystallizes the dielectric layer 126 into a predominantly tetragonal and/or crystalline structure, resulting in a low EOT and low leakage current density. Further reduction in the EOT is achieved by the use of a high work function metal electrode 130 capped with a second metal 156, which minimizes oxygen incorporation.

In other embodiments, the electrode material 130 preferably includes a gettering layer disposed therein or at a top surface thereof. In accordance with a second embodiment, the electrode material 130 comprises two or more material layers, wherein the gettering layer is deposited in a central portion or a top portion of the electrode material 130. A cross-sectional view of a semiconductor device 120 at various stages of manufacturing in accordance with this embodiment is shown in FIGS. 2 through 8, 10, and 11. Like materials and processes are preferably used in this embodiment as were used with reference to the first embodiment, and to avoid repetition, each element number and processing step in the drawings will not necessarily be described again herein.

The semiconductor device 120 is preferably fabricated by providing a workpiece 122, cleaning the workpiece (steps 102 and 104 of FIG. 1), and forming a nitride interface layer 124 over the workpiece 122 (step 106), as shown in FIG. 2. The dielectric layer 126 is formed over the nitride interface layer 124 (step 108) using process 140, as shown in FIG. 3 and in a more detailed view in FIG. 4. Alternatively, the dielectric layer 126 may be formed by depositing a single material layer or one or more material layers, for example. The dielectric layer 126 and workpiece 122 may be subjected to an optional post deposition anneal process 146 (step 110), as shown in FIG. 5.

An optional leakage-reducing layer 128 may be formed over the dielectric layer 126 (step 112 of FIG. 1), as shown in FIG. 6. However, alternatively, the leakage-reducing layer 128 may not be included: the electrode material 130 may be formed directly over the dielectric layer 126, as in the first embodiment.

Next, an electrode material 130 is formed over the dielectric layer 126, or over the leakage-reducing layer 128 if present in the structure (step 114 in FIG. 1), as shown in FIG. 7. FIG. 8 shows a more detailed view of the electrode material 130 in this embodiment.

The electrode material 130 is preferably formed by forming a first material layer 150 over the dielectric layer 126 (or leakage-reducing layer 128), and forming at least one second material layer over the first material layer 150, shown at 152a; or forming at least one material layer within the first material layer 150, shown in phantom at 152b. The at least one second material layer 152a or 152b is different than the first material layer 150; e.g., the second material layer 152a or 152b preferably comprises a different material than the material of the first material layer 150.

The first and second material layers 150 and 152a or 152b of the electrode material 130 preferably comprise conductive materials. The first material layer 150 is also referred to herein as a first conductive material 150, and the second material layer 152a or 152b is also referred to herein as a second conductive material 152a or 152b, for example. The second material layer 152a or 152b preferably comprises a material adapted to getter oxygen away from underlying material layers in order to reduce the EOT of the dielectric stack comprising the nitride interface layer 124, the dielectric layer 126 and/or the optional leakage-reducing layer 128. The second material layer 152a or 152b preferably has a high solubility for oxygen, for example. The second material layer 152a or 152b is also referred to herein as a gettering material or gettering layer, for example.

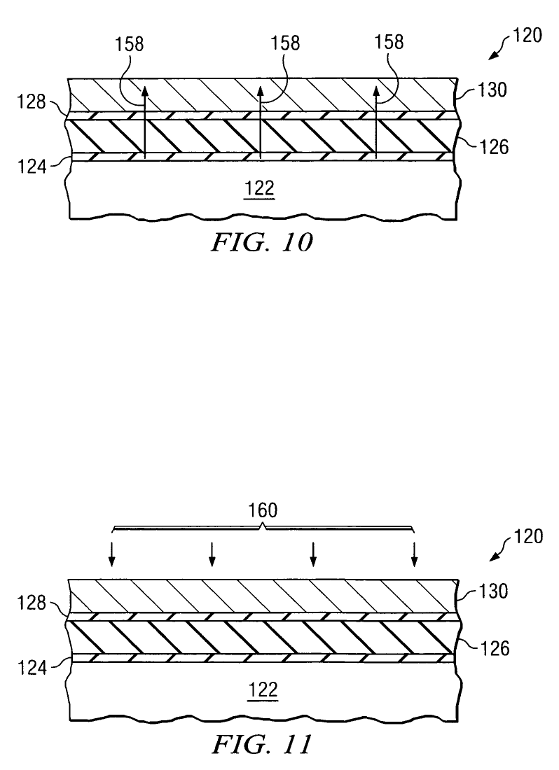

After forming the nitride interface layer 124 over the workpiece 122, the nitride interface layer 124 may comprise oxygen 158, for example, as shown in a cross-sectional view in FIG. 10. The gettering material 152a or 152b of the electrode material 130 is adapted to cause movement of at least a portion of the oxygen 158 upwardly from the nitride interface layer 124 through the dielectric layer 126 and the optional leakage-reducing layer 128 to the gettering material 152a or 152b of the electrode material 130. The oxygen 158 may bond with the gettering material or layer 152a or 152b, for example.

Referring again to FIG. 8, the electrode material 130 may comprise a gettering material 152b disposed at a central region of the electrode material 130, e.g., surrounded on both sides by the first material 150. Forming the electrode material 130 may comprise forming the first material 150, forming the second material 152b comprising the gettering material, and then forming additional first material 150 over the second material 152b, for example, wherein the first material 150 disposed over the second material 152b comprises the same material as the first material 150 beneath the second material 152b. Alternatively, the material 150 over the second material 152b in FIG. 8 may comprise at least one third conductive material disposed over the second conductive material 152b. The at least one third conductive material 150 formed over the second conductive material 152b may comprise a material that is different than the first conductive material 150 beneath the second material 152b, for example.

Alternatively, the electrode material 130 may comprise a gettering material 152a disposed at a top region of the electrode material, e.g., disposed over the first material layer 150. Thus, the gettering material 152a may comprise a top metal layer of the electrode material 130.

The first material layer or first conductive material 150 of the electrode material 130 may be formed by depositing TiN, TaN, TiSiN, TaSiN, TiHfN, TaHfN, Ti, Ta, and/or bi-layers thereof, by metal oxide chemical vapor deposition (MOCVD), physical vapor deposition (PVD), or other deposition methods, for example. The first material layer 150 may comprise a bi-layer, e.g., a bi-layer of a lower layer of TiN and an upper layer of TiSiN, for example, wherein the TiSiN comprises a thickness of about 2 nm or less, for example.

The second material layer 152a or 152b preferably comprises a gettering material comprised of Ti, Ta, Hf, and/or Si in some embodiments. If the second conductive material 152a or 152b comprises Si, the second conductive material 152a or 152b may be formed using a silane flash process, e.g., by introducing silane gas (SiH₄) into the processing chamber during or at the end of the first conductive material 150 deposition. If the second conductive material 152a or 152b comprises a metal, the second conductive material 152a or 152b may be formed using ALD, e.g., plasma enhanced ALD, or by the use of a reducing gas such as hydrogen. Alternatively, the second conductive material 152a or 152b may be deposited using other metal deposition processes and techniques.

The first material layer 150 may comprise a thickness of about 20 nm, and the second material layer 152a or 152b may comprise a thickness of about 20 Angstroms or less, or about 2 to 15 Angstroms in some embodiments, as examples, although alternatively, the first material layer 150 and the second material layer 152a or 152b may comprise other dimensions.

The gettering material, e.g., the Ti, Ta, Hf, or Si of the second conductive material 152a or 152b attracts oxygen from underlying material layers, minimizing their thickness, and also seals and covers grain boundaries between the underlying first material layer 150, e.g., grains of the first material layer 150, which may comprise TiN grains.

A layer of semiconductive material 154 may optionally be formed over the second conductive material 152a or the first or third material 150, as shown in FIG. 8. The electrode material 130 in this embodiment comprises the first material 150, the second material 152a and the semiconductive material 154; or the first material 150, the second material 152b, the first material or third material 150 disposed over the second material 152b, and the semiconductive material 154, for example.

The workpiece 122 is annealed (step 116 of FIG. 1) using a high temperature anneal process 160, as shown in FIG. 11. Advantageously, the anneal process 160 crystallizes the dielectric layer 126, and also causes gettering of oxygen from the nitride interface layer 124 to the gettering layer 152a or 152b of the electrode material 130, in this embodiment. The material layers 130, 128, 126, and 124 may then be patterned using lithography to form transistors or capacitors from at least the electrode material 130 and the dielectric layer 126 or 126/128 and nitride interface layer 124 (again, this is not shown in FIG. 11; see FIGS. 12 through 16, which will be described later herein).

The embodiment shown in and described with reference to FIGS. 2 through 8, 10, and 11 provides novel processing pathways and material selections that achieve a low leakage current and a low EOT, e.g., of the insulating materials 124, 126, and 128 and electrode material 130. This embodiment is also especially useful in metal-insulator-metal (MIM) capacitors and for DRAM applications, for example.

Experimental results of this embodiment of the present invention have demonstrated the efficacy of a top gettering layer 152a comprised of TiSiN included in the electrode material 130 as a diffusion barrier and gettering layer for oxygen during the activation anneal process 160, thus preventing or minimizing growth of the nitride interface layer 124. The incorporation of the optional leakage-reducing layer 128 comprised of Al₂O₃ formed immediately beneath the metal electrode 130 has shown to reduce leakage current. An electrode material 130 including a gettering layer of TiSiN has shown to minimize flatband voltage hysteresis and the rate of increase of the flatband voltage hysteresis with EOT. A further reduction in EOT of the dielectric stack comprising the nitride interface layer 124, the dielectric layer 126, and the optional leakage-reducing layer 128, can be achieved by optimizing the NH₃ pre-anneal process used to form the nitride interface layer 124, for example.

While the novel high temperature anneal process 160 causes the dielectric layer 126 to crystallize into a predominantly tetragonal structure, resulting in low EOT and low leakage current density, a further reduction in EOT is achieved by gettering oxygen from the high k-substrate interface using the gettering layer 152a or 152b of the metal electrode material 130.

In other embodiments, the high k dielectric material 126 comprises a crystalline high k phase of a dielectric material 126, such as in-situ nitrided hafnium silicon oxynitride (HfSiON). In accordance with a third embodiment, the dielectric layer 126 preferably comprises a material comprising a crystalline phase. A cross-sectional view of a semiconductor device 120 at various stages of manufacturing in accordance with this embodiment is shown in FIGS. 2 through 11. Like materials and processes are preferably used in this embodiment as were used with reference to the first embodiment, and to avoid repetition, each element number and processing step will not necessarily be described again herein.

In accordance with the third embodiment, a method of fabricating a semiconductor device 120 includes providing the workpiece 122, cleaning the workpiece 122, forming a nitride interface layer 124 over the workpiece, and forming a dielectric layer 126 over the nitride interface layer. The dielectric layer 126 preferably comprises a material comprising a crystalline phase; e.g., the dielectric layer 126 is preferably substantially crystalline rather than predominantly amorphous, after the semiconductor device 120 is formed. However, at this stage of the manufacturing process immediately after forming the dielectric layer 126, the dielectric layer 126 may be at least partially amorphous, for example.

The dielectric layer 126 preferably comprises in-situ nitrided HfSiON in some embodiments, for example, as previously described with reference to the first embodiment and FIGS. 3 and 4. The dielectric layer 126 may also comprise other in-situ nitrided materials, such as HfSiO, ZrSiON, ZrSiO, LaSiON, LaSiO, or other materials, for example. The dielectric layer 126 may also comprise HfSiO, for example. The dielectric layer 126 comprised of HfSiO may comprise a varying Si content; e.g., the dielectric layer 126 may comprise HfSiₓO, wherein x=0.2 to about 4, although x may comprise other values. The dielectric layer 126 may alternatively be formed by forming a plurality of nanolaminate material layers of HfO₂, HfO₂—Al₂O₃, HfO₂ with tetravalent dopant materials having ionic radii larger than Hf, HfO₂ with trivalent dopant materials having ionic radii larger than Hf, HfO₂ with divalent dopant materials having an ionic radii larger than Hf, and/or combinations or multiple layers thereof, for example.

Alternative dielectric materials that may be used for the dielectric layer 126 include tetravalent, trivalent, or divalent dopant materials disposed in hafnium oxide, zirconium oxide, or titanium dioxide, for example. One example of a tetravalent dopant material is Si. The trivalent dopant materials may comprise rare earth elements such as Gd, Dy, or Er, as examples. The divalent dopant materials may comprise Mg or Ca, as examples. The tetravalent, trivalent, and divalent dopant materials are included in the dielectric layer 126 to stabilize the cubic or tetragonal phases of the material 126, such as HfO₂ or ZrO₂, for example. Multiple layers or combinations of these materials, other dopant materials, and the previously mentioned materials may be used for the dielectric layer 126, for example.

The workpiece 122 is annealed in a nitrogen ambient using an anneal process 146 shown in FIG. 5, an electrode material 130 is formed over the dielectric layer 126, as shown in FIG. 7, and the workpiece 122 is preferably annealed at a temperature of greater than about 1,000 degrees C. using an anneal process 160 shown in FIG. 11. An optional leakage-reducing layer 128 may be included in the structure. The electrode material 130 may comprise a single layer of a material, such as about 10 nm of TiN or other thermally stable metal deposited by ALD or other methods, or alternatively, the electrode material 130 may comprise multiple layers and a gettering layer, as shown in and previously described herein with reference to FIGS. 8, 9, and 10.

Forming the dielectric layer 126 may comprise forming in-situ nitrided HfSiON comprising a low dielectric constant (k) phase, e.g., comprising at least a partially amorphous material. Advantageously, the final anneal process 160 shown in FIG. 11 may comprise annealing the workpiece at the temperature of greater than about 1,000 degrees C., which converts the dielectric layer 126 to a high k phase of the HfSiON, e.g., comprising a crystalline material. The high k phase of the HfSiON comprises a higher k value than the k value of the low k phase of the HfSiON, for example. The high temperature anneal process 160 advantageously stabilizes the high k phase of the dielectric layer 126, for example. The dielectric layer 126 may be formed by depositing other materials having a low k phase and later converting these materials to the high k phase using the novel anneal process 160, for example.

Advantages of the third embodiment include achieving a combination of low leakage current, e.g., less than about 1×10⁻⁷ to 1×10⁻⁸ A/cm² and a low EOT, e.g., of less than about 2 to 3 nm after a thermal budget exceeding about 1,000° C.

By choosing an appropriate high dielectric constant material, for example, in-situ nitrided hafnium silicon oxynitride, hafnium silicate, or other materials for the dielectric layer 126, and by subjecting the dielectric layer 126 to a high temperature rapid thermal anneal treatment above about 1,000° C., the dielectric layer 126 is advantageously crystallized into a predominantly tetragonal structure, resulting in low EOT and low leakage current density.

Experimental results have demonstrated that leakage current can be reduced by more than an order of magnitude after a 1,050° C. anneal process 160 in N₂ compared with a 1,000° C. anneal process 160, for example. The formation of the higher dielectric constant phase of the dielectric layer 126 was found to reduce the leakage current. Following a 1,050° C. anneal, a dielectric layer 126 comprising an in-situ nitrided HfSiON film deposited by atomic layer deposition was found to be crystalline, with a predominantly tetragonal HfO₂ structure, for example. A small fraction of monoclinic HfO₂ was found to be present in the dielectric layer 126 structure; however, the EOT and leakage current were still found to be significantly reduced.

Embodiments of the present invention also include combinations of the features and methods of the first, second and third embodiments, for example. Embodiments of the present invention include methods of manufacturing semiconductor devices and semiconductor devices manufactured using the methods described herein. While advantages are achieved by using a single layer electrode and a crystalline high k dielectric layer 126 as described in the third embodiment, synergistic effects and advantages are achieved by combining a crystalline high k dielectric layer 126 with a double layer electrode material 130 as described in the first embodiment or with an electrode material 130 comprising a gettering layer 152a or 152b, as described in the second embodiment, for example. Likewise, the first and second embodiments are useful and have advantages when a non-crystalline high k material is used for the dielectric layer 126 or when the dielectric layer 126 is formed by other methods than in-situ nitridation; however, synergistic effects and advantages are achieved by combining the first and second embodiments with the novel crystalline dielectric layer of the first embodiment, for example.

The material layers 124, 126, and optionally, also 128 described herein advantageously comprise a high k dielectric material stack that has a high k value, e.g., of about 25 or greater in some embodiments. In some embodiments, the material layers 124, 126, and 128 advantageously comprise a dielectric material stack that has a dielectric constant of greater than about 30 in some embodiments. The combined thickness of the material layers 124, 126, and 128 is preferably about 15 nm or less in accordance with some embodiments of the present invention, for example. Alternatively, the combined thickness of the material layers 124, 126, and 128 may be greater than about 15 nm, in other embodiments.

Referring again to FIG. 11, after the final high temperature anneal process 160, the various material layers 130, 128, 126, and 124 are then patterned into desired shapes for the semiconductor device 120. For example, the material layer 130 that is conductive may be patterned in the shape of a capacitor plate, a transistor gate, or other conductive elements or portions of circuit elements, as examples. The material layers 128, 126, and 124 comprising the dielectric stack that are insulators may also be patterned, for example.

The novel methods and structures described herein are shown implemented in a planar structure in FIGS. 2 through 11. The novel methods and structures of embodiments of the present invention may also be implemented in non-planar structures, for example.

FIGS. 12 and 13 show cross-sectional views of a semiconductor device 220 at various stages of manufacturing, wherein the novel processing methods, high k dielectric materials 124/126/128, and electrode materials 130 of embodiments of the present invention are implemented in a metal-insulator-metal (MIM) capacitor structure, for example. Like numerals are used for the various elements that were described in FIGS. 2 through 11. To avoid repetition, each reference number shown in FIGS. 12 and 13 is not described again in detail herein. Rather, similar materials x22, x24, x26, x28, x30, etc. . . . are preferably used for the various material layers shown as were used to describe FIGS. 2 through 11, where x=1 in FIGS. 2 through 11 and x=2 in FIGS. 12 and 13.

To form the MIM capacitor, a bottom capacitor plate 264 is formed over a workpiece 222. The bottom plate 264 may comprise a semiconductive material such as polysilicon, or a conductive material such as TiN, TaN, TiTaN, Ru, RuₓO, TiHfN, TiCN, TaCN, TiXN, AlN, Re₁Re₂N, wherein X comprises a rare earth or transition metal element, wherein RE₁RE₂N comprises a nitride of a first rare earth element RE₁ and a second rare earth element RE₂, and wherein the second rare earth element comprises a different rare earth element than the first rare earth element, as examples, although other materials such as a semiconductor material, e.g., polysilicon may also be used. The bottom capacitor plate 264 may be formed in an insulating material 262a that may comprise an inter-level dielectric layer (ILD), for example. The bottom capacitor plate 264 may include liners and barrier layers, for example, not shown.

The novel high k dielectric material 224/226/228 described with reference to FIGS. 1 through 11 is formed over the bottom plate 264 and the insulating material 262a. An electrode material 230 is formed over the dielectric material 224/226/228, as shown in FIG. 12, and the electrode material 230 is patterned to form a top capacitor plate, as shown in FIG. 13. An additional insulating material 262b may be deposited over the top capacitor plate 230, and the insulating material 262b may be patterned with patterns 266a and 266b for contacts that will make electrical contact to the top plate 230 and the underlying bottom plate 264, respectively. The insulating material 262b may be filled in later with a conductive material to form the contacts in patterns 266a and 266b, for example, not shown.

Thus, in FIG. 13, a capacitor is formed that includes the two conductive plates 264 and 230 separated by an insulator which comprises the novel high k dielectric material 224/226/228 and the novel electrode material 230 for the top plate 230 in accordance with embodiments of the present invention. The capacitor may be formed in a front-end-of the line (FEOL), or portions of the capacitor may be formed in a back-end-of the line (BEOL), for example. One or both of the capacitor plates 264 and 230 may be formed in a metallization layer of the semiconductor device 220, for example. Capacitors such as the one shown in FIG. 13 may be used in filters, in analog-to-digital converters, memory devices, control applications, and many other types of applications, for example.

FIG. 14 shows a cross-sectional view of a semiconductor device 320 wherein the novel processing methods, high k dielectric material 324/326/328, and electrode material 330 of embodiments of the present invention are implemented in a transistor structure. The high k dielectric material 324/326/328 is implemented as a gate dielectric material 324/326/328, and the electrode material 330 is implemented as a transistor gate. Again, like numerals are used for the various elements that were used to describe the previous figures, and to avoid repetition, each reference number shown in FIG. 14 is not described again in detail herein.

The transistor includes a gate dielectric comprising the novel high k dielectric material layer 324/326/328 described herein and a gate electrode 330 formed over the high k dielectric material layer 324/326/328. Source and drain regions 370 are formed proximate the gate electrode 330 in the workpiece 322, and a channel region is disposed between the source and drain regions 370 in the workpiece 322. The transistor may be separated from adjacent devices by shallow trench isolation (STI) regions 372, and insulating spacers 374 may be formed on sidewalls of the gate electrode 330 and the gate dielectric 324/326/328, as shown.

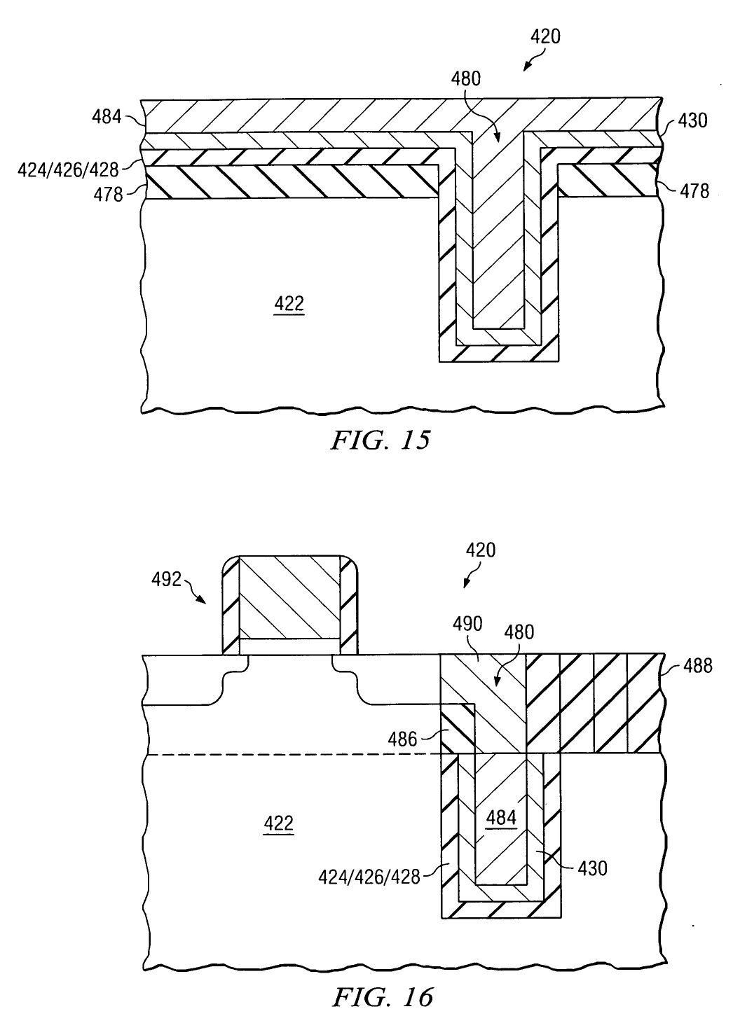

FIGS. 15 and 16 show cross-sectional views of a semiconductor device 420 at various stages of manufacturing, wherein the novel processing methods, high k dielectric material 424/426/428, and electrode materials 430 of embodiments of the present invention are implemented in a DRAM structure. To form a DRAM memory cell comprising a storage capacitor utilizing the novel high k dielectric material 424/426/428 of embodiments of the present invention, a sacrificial material 478 comprising an insulator such as a hard mask material is deposited over a workpiece 422, and deep trenches 480 are formed in the sacrificial material 478 and the workpiece 422. The novel high k dielectric material layer 424/426/428 is formed over the patterned sacrificial material 478 and the workpiece 422, and an electrode material 430 is formed over the high k dielectric material layer 424/426/428, as shown. An additional electrode material 484 comprising polysilicon that may be doped with n or p-type doping, for example, or other semiconductor or conductive material may be deposited over the electrode material 430 to fill the trenches 480, as shown in FIG. 15.

Next, excess amounts of electrode materials 484 and 430 and dielectric materials 424/426/428 are removed from over the top surface of the workpiece 422, e.g., using a chemical mechanical polish (CMP) process and/or etch process. The materials 484 and 430, and high k dielectric material layer 424/426/428 are also recessed below the top surface of the workpiece 422, for example. The sacrificial material 478 is also removed, as shown in FIG. 16.

An oxide collar 486 may be formed by thermal oxidation of exposed portions of the trench 480 sidewalls. The trench 480 may then be filled with a conductor such as polysilicon 490. Both the polysilicon 490 and the oxide collar 486 are then etched back to expose a sidewall portion of the workpiece 422 which will form an interface between an access transistor 492 and the capacitor formed in the deep trench 480 in the workpiece 422, for example.

After the collar 486 is etched back, a buried strap may be formed at 490 by deposition of a conductive material, such as doped polysilicon. Regions 484 and 490 comprising polysilicon are preferably doped with a dopant such as arsenic or phosphorus, for example. Alternatively, regions 484 and 490 may comprise a conductive material other than polysilicon (e.g., a metal).

The strap material 490 and the workpiece 422 may then be patterned and etched to form STI regions 488. The STI regions 488 may be filled with an insulator such as an oxide deposited by a high density plasma process (i.e., HDP oxide). The access transistor 492 may then be formed to create the structure shown in FIG. 16.

The workpiece 422 proximate the high k dielectric material layer 424/426/428 lining the deep trench 480 comprises a first capacitor plate, the high k dielectric material layer 424/426/428 comprises a capacitor dielectric, and materials 430 and 484 comprise a second capacitor plate of the deep trench storage capacitor of the DRAM memory cell. The access transistor 492 is used to read or write to the DRAM memory cell, e.g., by the electrical connection established by the strap 490 to a source or drain of the transistor 492 near the top of the deep trench 480, for example.

Embodiments of the present invention may also be implemented in other structures that require a dielectric material. For example, the novel processing methods, high k dielectric material layers, and electrode materials described herein may be implemented in planar transistors, vertical transistors, planar capacitors, stacked capacitors, vertical capacitors, deep or shallow trench capacitors, and other devices. Embodiments of the present invention may be implemented in stacked capacitors where both plates reside above a substrate or workpiece, for example.

Advantages of embodiments of the present invention include providing novel methods and structures having a high dielectric constant or k value. The structures formed are thermally stable and result in capacitors having a low effective oxide thickness (EOT) and low leakage current, for example.

The entire dielectric stack of the high k materials 124/126/128, 224/226/228, 324/326/328, and 424/426/428 described herein, advantageously may have a dielectric constant of about 25 or greater in some embodiments, and more preferably has a dielectric constant of greater than 30 in other embodiments, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of fabricating a semiconductor device, the method comprising:
providing a workpiece;
forming a dielectric layer over the workpiece, the dielectric layer comprising a crystalline phase; and
forming an electrode material over the dielectric layer.

2. The method according to claim 1, wherein forming the dielectric layer comprises forming a hafnium-containing material, a zirconium-containing material, a titanium-containing material, or in-situ nitrided HfSiON, HfSiO, ZrSiON, ZrSiO, LaSiON, or LaSiO.

3. The method according to claim 1, wherein forming the dielectric layer comprises in-situ nitridation of the dielectric layer.

4. The method according to claim 1, wherein forming the dielectric layer comprises forming HfSiO, or wherein forming the dielectric layer comprises forming a plurality of nanolaminate material layers of HfO₂, HfO₂—Al₂O₃, HfO₂ with tetravalent dopant materials having ionic radii larger than Hf, HfO₂ with trivalent dopant materials having ionic radii larger than Hf, HfO₂ with divalent dopant materials having ionic radii larger than Hf, tetravalent, trivalent, or divalent dopant materials disposed in hafnium oxide, zirconium oxide, or titanium dioxide, and/or combinations or multiple layers thereof.

5. The method according to claim 1, wherein forming the electrode material comprises forming an electrode material including a first material layer and at least one second material layer disposed over the first material layer, wherein the at least one second material layer is different than the first material layer.

6. The method according to claim 1, wherein forming the electrode material comprises forming an electrode material including a first material layer and at least one second material layer disposed over the first material layer, wherein the at least one second material layer comprises a gettering material.

7. A semiconductor device manufactured using the method according to claim 1.

8. A method of fabricating a semiconductor device, the method comprising:
providing a workpiece;
cleaning the workpiece;
forming a nitride interface layer over the workpiece;
forming a dielectric layer over the nitride interface layer;
annealing the workpiece in a nitrogen ambient;
forming an electrode material over the dielectric layer; and
annealing the workpiece at a temperature sufficient to crystallize the dielectric layer.

9. The method according to claim 8, wherein forming the dielectric layer comprises forming the dielectric layer using atomic layer deposition (ALD).

10. The method according to claim 8, wherein annealing the workpiece comprises annealing the workpiece at a temperature of greater than about 1,000 degrees C. for greater than about 5 seconds in an ambient of N₂, and wherein the N₂ concentration is greater than about 90%.

11. The method according to claim 8, wherein forming the dielectric layer comprises forming a low dielectric constant (k) phase of the dielectric layer, wherein annealing the workpiece converts the dielectric layer to a high k phase of the dielectric layer, and wherein the high k phase of the dielectric layer comprises a higher k value than the k value of the low k phase of the dielectric layer.

12. A method of fabricating a semiconductor device, the method comprising:
providing a workpiece;
forming a dielectric layer over the workpiece, wherein forming the dielectric layer comprises in-situ nitridation of a dielectric material and/or forming a dielectric material having a crystalline phase; and
forming an electrode material over the dielectric layer, the electrode material including a first material layer and at least one second material layer disposed over the first material layer, wherein the at least one second material layer is different than the first material layer.

13. The method according to claim 12, wherein forming the electrode material comprises forming an electrode material wherein the at least one second material layer comprises a gettering material disposed at a central region or a top region of the electrode material.

14. The method according to claim 12, wherein forming the electrode material comprises forming an electrode material wherein the at least one second material layer comprises a gettering material comprised of Ti, Ta, Hf, and/or Si.

15. The method according to claim 12, further comprising annealing the workpiece at a temperature of greater than about 1,000 degrees C. after forming the electrode material.

16. The method according to claim 12, wherein forming the electrode material further comprises forming a layer of semiconductive material over the second material layer.

17. The method according to claim 12, further comprising forming a transistor or a capacitor from at least the electrode material and the dielectric layer.

18. A semiconductor device manufactured in accordance with the method of claim 12.

19. A method of fabricating a semiconductor device, the method comprising:
providing a workpiece;
cleaning the workpiece;
forming a nitride interface layer over the workpiece;
forming a dielectric layer over the nitride interface layer;
annealing the workpiece; and
forming an electrode material over the dielectric layer, wherein forming the electrode material comprises forming a first conductive material over the dielectric layer, and forming a second conductive material over the first conductive material, wherein forming the second conductive material comprises forming a gettering material.

20. The method according to claim 19, wherein after forming the nitride interface layer over the workpiece, the nitride interface layer comprises oxygen, and wherein the gettering material of the electrode material is adapted to cause movement of at least a portion of the oxygen upwardly from the nitride interface layer to the gettering material.

21. The method according to claim 19, wherein forming the first conductive material comprises forming TiN, TaN, TiSiN, TaSiN, TiHfN, TaHfN, Ti, Ta, and/or bi-layers thereof, and wherein forming the second conductive material comprises forming Ti, Ta, or Hf using a metal deposition process, or forming Si by exposing the first conductive material to a silane flash process.

22. The method according to claim 19, wherein forming the second conductive material comprises forming a top metal layer of the electrode material.

23. The method according to claim 19, further comprising forming at least one third conductive material over the second conductive material.

24. The method according to claim 23, wherein forming the at least one third conductive material comprises forming a material that is the same as, or different than, the first conductive material.

25. A method of fabricating a semiconductor device, the method comprising:
providing a workpiece;
cleaning the workpiece;
forming a nitride interface layer over the workpiece;
forming a dielectric layer over the workpiece;
annealing the workpiece; and
forming an electrode material over the dielectric layer, wherein forming the electrode material comprises forming a first conductive material over the dielectric layer, and forming a second conductive material over the first conductive material, wherein the second conductive material is different than the first material.

26. The method according to claim 25, wherein forming the electrode material comprises placing the workpiece in a chamber, applying a vacuum to the chamber, and forming the first conductive material and the second conductive material while maintaining the vacuum in the chamber.

27. The method according to claim 25, wherein forming the electrode material comprises forming an electrode material wherein the first conductive material comprises TaCN, TiSiN, TiHfN, or MoAlN and wherein the second conductive material comprises TiN or TaN.

28. The method according to claim 25, wherein forming the dielectric layer comprises forming a first insulating material and forming a second insulating material over the first insulating material, wherein the second insulating material comprises a leakage-reducing layer.

29. The method according to claim 28, wherein forming the second insulating material comprises forming Al₂O₃, HfOₓ, or HfSiOₓ.

30. The method according to claim 25, wherein forming the dielectric layer comprises forming a material having a predominantly tetragonal HfO₂ structure or at least one layer of HfSiON, ZrSiON, or LaSiON.
